(19) United States
(12) Patent Application Publication
(10) Pub. No.: US 2024/0311323 A1
(43) Pub. Date: Sep. 19, 2024

(54) FANOUT CONNECTIONS ON A HIGH-PERFORMANCE COMPUTING DEVICE

(71) Applicant: Samsung Electronics Co., Ltd., Suwon-si (KR)

(72) Inventors: Eric Richard BORCH, Fort Collins, CO (US); Casey Glenn THIELEN, Chandler, AZ (US); Alan GARA, Palo Alto, CA (US); Young Jun HONG, Seoul (KR)

(21) Appl. No.: 18/232,819

(22) Filed: Aug. 10, 2023

Related U.S. Application Data
(60) Provisional application No. 63/452,684, filed on Mar. 16, 2023.

(51) Int. Cl. G06F 13/40; G06F 11/34

(52) U.S. Cl. CPC G06F 13/4022; G06F 11/3495

(57) ABSTRACT

Embodiments disclose methods, systems and devices including a plurality of connectors, a plurality of switches, and a plurality of compute elements. Each of the plurality of compute elements may be connected to each of the plurality of switches. In some embodiments, a first subset of the plurality of switches may be directly connected to a first subset of the plurality of the connectors in a fanout mechanism, and a second subset of the plurality of switches may be directly connected to a second subset of the plurality of the connectors in a similar fanout mechanism.

### CROSS-REFERENCE TO RELATED APPLICATION

This application claims the priority benefit under 35 U.S.C. § 119(e) of U.S. Provisional Patent Application Ser. No. 63/452,684, filed on Mar. 16, 2023, the disclosure of which is incorporated herein by reference in its entirety.

### TECHNICAL FIELD

The subject matter disclosed herein generally relates to High-Performance Computing systems. More specifically, the subject matter disclosed herein relates to Printed Circuit Boards and connections between different devices.

### BACKGROUND

Many complex real-world problems are being solved nowadays on High-Performance Computing (HPC) devices that offer very high levels of parallel computing. Examples of areas where HPCs are used include modeling of weather and climates, Nuclear and Scientific research, and many areas of Artificial Intelligence (AI) calculations of datasets. HPCs may use a greater number of processors or compute elements than regular personal computers.

The above information disclosed in this Background section is only for enhancement of understanding of the background of the invention and therefore it may contain information that does not constitute prior art.

### BRIEF SUMMARY

An example embodiment includes a device with a plurality of connectors. The device may include a plurality of switches. The device may also include a plurality of compute elements, where each of the plurality of compute elements is connected to each of the plurality of switches, and a first subset of the plurality of switches is directly connected to a first subset of the plurality of the connectors via a fanout mechanism, and a second subset of the plurality of switches is directly connected to a second subset of the plurality of the connectors via the fanout mechanism. In some embodiments the device may be a printed circuit board (PCB) that connects to other PCBs via the plurality of connectors, as part of an HPC system. In some embodiments, the first plurality of switches are half of the plurality of switches and the first subset of the plurality of connectors are half of the plurality of connectors. The device, in other embodiments may be a PCB that connects to other PCBs via the plurality of connectors and each connector of the plurality of connectors connects to two other PCBs. In further embodiments, the first plurality of switches and second plurality of switches may each be one quarter of the plurality of switches and the first subset of the plurality of connectors and second plurality of connectors is each one quarter of the plurality of connectors. In yet further embodiments, the device may be a PCB where each of the plurality of connectors connects to 4 other PCBs. Further, each of the plurality of compute elements may be one of: a graphics processing units (GPUs), central processing units (CPUs), tensor processing units (TPUs), neural processing units (NPUs), vision processing units (VPUs), field programmable gate arrays (FPGAs), or a microprocessor in some embodiments. Implementations of the described techniques may include hardware, a method or process, or computer software on a computer-accessible medium.

Another example embodiment includes a device with a plurality of connectors. The device may also include a plurality of switches. Further, the device may include a plurality of compute elements, where each of the plurality of compute elements is connected to each of the plurality of switches, and the plurality of switches is each directly connected to the plurality of the connectors via a fanout mechanism, and each of the plurality of the connectors connects to one other device. In some embodiments, the device may be a PCB that connects to other PCBs via the plurality of connectors and each connector of the plurality of connectors connects to one other PCB. The device may be a PCB that connects to other PCBs via the plurality of connectors, as part of a HPC system, in other embodiments. In yet further embodiments, each of the plurality of compute elements may be one of: GPUs, CPUs, TPUs, NPUs, VPUs, FPGAs, or microprocessors. Implementations of the described techniques may include hardware, a method or process, or computer software on a computer-accessible medium.

Another example embodiment, includes a high-performance computing system with a plurality of circuit boards each including a plurality of compute elements, a plurality of switches, and a plurality of connectors. Each of the plurality of circuit boards may be connected where each of the plurality of compute elements is connected to each of the plurality of switches, and a first subset of the plurality of switches is directly connected to a first subset of the plurality of the connectors via a fanout mechanism, and a second subset of the plurality of switches is directly connected to a second subset of the plurality of the connectors via the fanout mechanism on its respective circuit board of the plurality of circuit boards. In some embodiments, the first plurality of switches is half of the plurality of switches and the first subset of the plurality of connectors is half of the plurality of connectors. The routing device may communicate with the plurality of compute elements and perform throttling to manage the bandwidth and processing loads of the plurality of circuit boards and compute elements, in some embodiments. In some embodiments, each of the plurality of compute elements is one of: a GPUs, CPUs, TPUs, NPUs, VPUs, FPGAS, or a microprocessor. The high-performance computing system may include a routing device connected to the plurality of circuit boards which routes tasks to the plurality of compute elements. Implementations of the described techniques may include hardware, a method or process, or computer software on a computer-accessible medium.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an exemplary Data Center, according to some embodiments.

FIG. 2 illustrates an orthogonal board connected system according to some embodiments.

FIG. 3 illustrates connected PCBs according to some embodiments.

FIG. 4 illustrates connected PCBs according to some embodiments.

FIG. 5 illustrates connected PCBs according to some embodiments.

FIG. 6 illustrates a detailed connected board with fanout according to some embodiments.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT.” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on.” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system-on-a-chip (SoC), an assembly, and so forth.

Fields such as Artificial Intelligence, climate or weather simulation, or various Physics and Nuclear Reactor simulations have very high-speed requirements. These areas are very good for HPC where many more compute elements than a typical computer may be utilized. The distributed systems and additional compute power enables parallel processing of large problems or performing repetitive tasks for very large data sets. In one example, for climate modeling the whole Earth may be divided into small pieces and each of those pieces may get assigned to one of the compute elements on a simulation.

Building a very large node in HPC, for example one with more than 512 compute elements, may require a large amount of bandwidth between the compute elements and/or boards. Actualizing a high all-to-all bandwidth using a minimal number of hops may demand a large number of interconnected components. Connecting so many components may be difficult because of heating, and the space needed for so much wiring. Thousands of cables would be used for such devices in HPC among existing solutions.

A node on an HPC device may be defined as a single processor, a set of processors on a single PCB, or a set of PCBs interconnected on one or more racks. A node in some embodiments may include hundreds or thousands of compute elements all working in synchronization. A large amount of bandwidth as well as low latencies may be necessary to have communication between PCBs, as well as between racks. Minimizing the number of hops between switches is beneficial to accomplish this low latency and high bandwidth preference. As connections between PCBs and compute elements increases, so does the difficulty in connecting many boards, switches, and racks.

According to embodiments disclosed herein, some nodes may share some or all of the memory on a PCB, or a rack of nodes. In connecting many compute elements on different PCBs the number of connections needed to connect together boards may become extremely large. For example, if 512 compute elements were connected among various boards then the number of connections may become over 250,000 (512*511). Orthogonal boards may help alleviate this problem, according to some embodiments. In further embodiments, connecting every switch, or a group of switches to all of the connectors, or different groups of the connectors, may be used to reduce the number of connectors being used.

Embodiments of the subject matter described herein may fan out wires from each switch to every connector on a single PCB having multiple compute elements. The switches may then connect through a single cable to another PCB, rather than multiple cables. In connecting multiple PCBs the arrangement may be varied from orthogonal to other arrangements. Single cables may carry data from all of the compute elements to another board (PCB). Bandwidth may be similar to various embodiments with every switch connected every connector. In some embodiments, for example, switches may have 32 ports exiting the connector and 32 ports entering the connector. Each port, in some embodiments, may be directly connected on the PCB to the same connector. In some embodiments, the network bandwidth may be distributed among all the switches on a board. In each connector, there may be a pin for each connection coming in from the switch, and going out to a single cable (to another PCB).

In some of the embodiments described herein, all of the compute elements on a board may connect to all of the switches on the board. Groups of switches may then connect to groups of connections in a fanout mechanism or structure on the board itself. For example, a board with 32 switches may be grouped into 2, 4 or 8 groups. If grouped linearly, the groups would have 16, 8, or 4 switches in each group. Each group may connect similarly to a group of the same number of connections in a fanout pattern wired on the PCB. In a group of ½ of the switches on the board, each connection may connect to 2 other boards. A group of ¼ of the switches on the board, may connect to 4 other boards for each connection. Finally, a group of ⅛ of the switches on the board may connect ⅛ of the connectors, and then to 8 other boards for each connector.

A fanout structure or mechanism may include partial groups or all of the switches connecting directly to individual connectors. A fanout may refer to the on-board wiring of, for example, 16 switches directly connecting to a single connector. A fanout may further identify the direct wiring from all of or groups of switches to each connector, i.e. each grouping of wiring may be considered a fanout. Therefore, a fanout between switches 1-16 to connector 1 is a fanout, as well as between switches 1-16 to connector 2, and between switches 1-16 to connector 3, etc.

In some embodiments the switches may be connected via one or more standardized communications protocol like CXL, or PCIe. In another embodiment, the switches may be connected to the compute elements via a customized communications methodology or protocol.

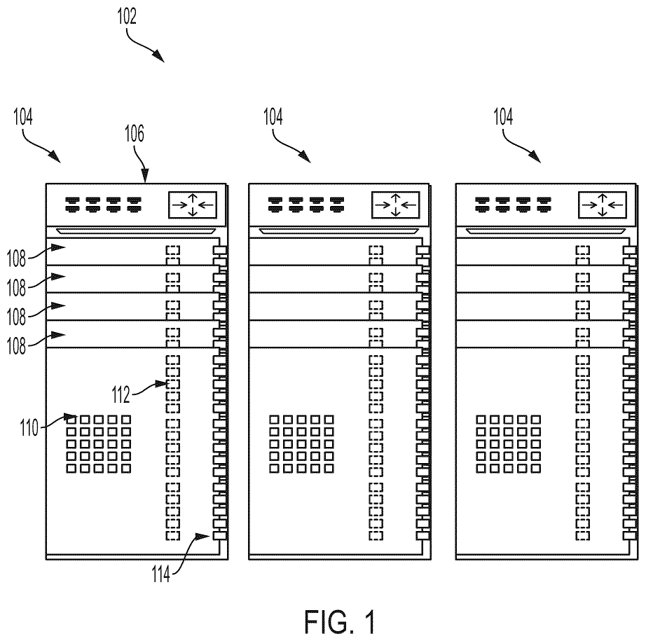

FIG. 1 illustrates an exemplary Data Center 102, according to some embodiments. In some embodiments, one or more Data Center Racks 104 may be used including any number of Compute Element PCBs 108. Each Data Center Rack 104 may have, for example, a Top of Rack Router 106 which includes a routing device receiving signaling and passing on processing or data requests to Compute Element PCBs 108.

Each of the Compute Element PCBs 108 may have any number of Compute Elements 110, Switches 112 and Connectors 114. In some examples the Compute Elements 110 may be Graphics Processing Units (GPUs), Central Processing Units (CPUs), Tensor Processing Units (TPUs), Neural Processing Units (NPUs), Vision Processing Units (VPUs), Field Programmable Gate Arrays (FPGAs), Quantum Processors, Microprocessors, Physics Processing Units, etc. The arrangement of the processors may be in any manner, including a grid, a line, an organic arrangement, etc. These are intended as examples and not to limit the variation on embodiments. The number of Compute Elements 110 in some embodiments may be a factor of two, for example, 8, 16, 32 or 64 Compute Elements. As illustrated 25 Compute Elements 110 are on each Compute Element PCB 108.

In some embodiments, the HPC may have one or more service or management nodes on one or more Top of Rack Routers 106. Processing jobs may get input to the HPC and the service or management nodes may assign or search for Compute Elements 110 that are free or available. The tasks may get distributed down to individual Compute Element PCBs 108. As the Compute Elements 110 may finish their tasks or processing jobs they may write the results to local or centralized storage (shared in the one or more racks) and communicate back to the scheduler that it has finished.

Any of the functionality disclosed herein may be implemented with hardware, software, or a combination thereof including combinational logic, sequential logic, one or more timers, counters, registers, and/or state machines, one or more complex programmable logic devices (CPLDs), FPGAs, application specific integrated circuits (ASICs), CPUs such as complex instruction set computer (CISC) processors such as x86 processors and/or reduced instruction set computer (RISC) processors such as ARM processors, GPUs, NPUs, TPUs and/or the like, executing instructions stored in any type of memory, or any combination thereof. In some embodiments, one or more components may be implemented as a system-on-chip (SOC).

In some embodiments storage may be on individual Compute Element PCBs 108, as separate nodes, or as part of the Top of Rack Routers 106. Any variation on amount, location and configuration of storage may be considered. Any of the storage devices disclosed herein may communicate through any interfaces and/or protocols including Peripheral Component Interconnect Express (PCIe), Nonvolatile Memory Express (NVMe), NVMe-over-fabric (NVMe-oF), Ethernet, Transmission Control Protocol/Internet Protocol (TCP/IP), User Datagram Protocol (UDP), remote direct memory access (RDMA), RDMA over Converged Ethernet (ROCE), FibreChannel, InfiniBand, Serial ATA (SATA), Small Computer Systems Interface (SCSI), Serial Attached SCSI (SAS), iWARP, Hypertext Transfer Protocol (HTTP), and/or the like, or any combination thereof.

In the embodiments described herein, the operations are example operations, and may involve various additional operations not explicitly illustrated. In some embodiments, some of the illustrated operations may be omitted. In some embodiments, one or more of the operations may be performed by components other than those illustrated herein. Additionally, in some embodiments, the temporal order of the operations may be varied.

The Compute Element PCBs 108 may include any number of Switches 112. Switches in some embodiments, may be any type of network switch which provides packet switching, for example. The switch may be used for Ethernet as well as Fibre Channel, RapidIO, Asynchronous Transfer Mode, and InfiniBand, for example. Additionally, the switches may be configured as unmanaged switches, managed switches, smart switches or enterprise managed switches. The management features for the switches may include enabling and disabling ports, link bandwidth, QoS, Medium Access Control (MAC) filtering, Spanning Tree Protocol (STP) and Shortest Path Bridging (SPB) features. Further, the switches may be able to provide port mirroring, link aggregation, and Network Time Protocol (NTP) synchronization. These are just a few features and not intended as limiting.

The Compute Element PCBs 108 may also include any number or configuration of Connectors 114. In some embodiments, board to board connectors may be used such as backplane connectors, high pin count connectors, or high density interface connectors. In other embodiments, flyover cables may be used to connect one board to another board, and plugged into one or more cabling assemblies. Any type of plug or connector may be considered for Connectors 114. Additionally, the Connectors 114 may have input slots or ports for board signal routing received from the Switches 112.

Some embodiments may consider a variation on processing devices used for Compute Elements 110. For example, one or more storage nodes or devices in place of or in conjunction with the Compute Element 110. The one or more storage nodes may be implemented with any type and/or configuration of storage resources. For example, in some embodiments, one or more of the Compute Elements 110 may be storage nodes implemented with one or more storage devices such as hard disk drives (HDDs) which may include magnetic storage media, solid state drives (SSDs) which may include solid state storage media such as not-AND (NAND) flash memory, optical drives, drives based on any type of persistent memory such as cross-gridded nonvolatile memory, memory with bulk resistance change, and/or the like, and/or any combination thereof. In some embodiments, the one or more storage devices may be implemented with multiple storage devices arranged, for example, in one or more servers. They may be configured, for example, in one or more server chassis, server racks, groups of server racks, datarooms, datacenters, edge data centers, mobile edge datacenters, and/or the like, and/or any combination thereof. In some embodiments, the one or more storage nodes 102 may be implemented with one or more storage server clusters.

Data Center 102 may be implemented with any type and/or configuration of network resources. For example, in some embodiments, Data Center 102 may include any type of network fabric such as Ethernet, Fibre Channel, InfiniBand, and/or the like, using any type of network protocols such as Transmission Control Protocol/Internet Protocol (TCP/IP), Remote Direct Memory Access (RDMA) over Converged Ethernet (ROCE), and/or the like, any type of storage interfaces and/or protocols such as Serial ATA (SATA), Small Computer Systems Interface (SCSI), Serial Attached SCSI (SAS), Non-Volatile Memory Express (NVMe), NVMe-over-fabric (NVMe-oF), and/or the like. In some embodiments, the Data Center 102 and Data Center Racks 104 may be implemented with multiple networks and/or network segments interconnected with one or more switches, routers, bridges, hubs, and/or the like. Any portion of the network or segments therefore may be configured as one or more local area networks (LANs), wide area networks (WANs), storage area networks (SANs), and/or the like, implemented with any type and/or configuration of network resources. In some embodiments, some or all of the Top of Rack Routers 106 may be implemented with one or more virtual components such as a virtual LAN (VLAN), virtual WAN, (VWAN), and/or the like.

The semiconductor devices described above and below, may be encapsulated using various packaging techniques. For example, semiconductor devices constructed according to principles of the disclosed subject matter may be encapsulated using any one of a package on package (POP) technique, a ball grid arrays (BGAs) technique, Land Grid Array (LGA), a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique, a wafer-level processed stack package (WSP) technique, or other technique as will be known to those skilled in the art.

Compute Element PCBs 108 within Data Center Racks 104 may be connected using any inter-board communication and data transfer protocol known in the art. The Compute Element PCBs 108 and/or Top of Rack Routers 106 may also have sophisticated power supplies including consideration for heat and cooling of the systems. The Data Center Racks 104 may account for electrical surges, overheating using various cooling systems and surge protectors. The Top of Rack Routers 106 and configuration of the Compute Element PCBs 108 may account for high-speed data transfers within and across the PCBs or racks. Further latency may be minimized based on the connection and on-board wiring configuration. Finally, wiring and connections may be organized to ensure sufficient cooling capabilities and/or heat dissipation.

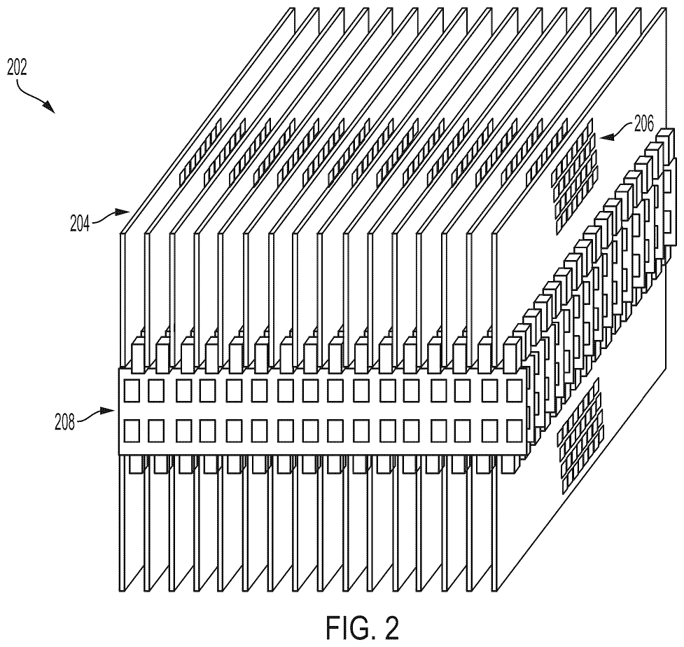

FIG. 2 illustrates an orthogonal board connected system according to some embodiments. The system comprises an Orthogonal Board Rack 202, including an Orthogonal Board 204, Compute Elements 206, and Switch Boards 208. In some embodiments, an Orthogonal Board Rack 202 may be used where Orthogonal Boards 204 or PCBs are arranged in one or more grid patterns and stacked vertically into, for example, a crossbar switch, a mesh or other topology. Switch Boards 208 may directly connect one board on top to a second board on the bottom. Compute Elements 206 may then interact from one board to another. In additional embodiments, cables may be used to connect different boards together in a more horizontally stacked structure.

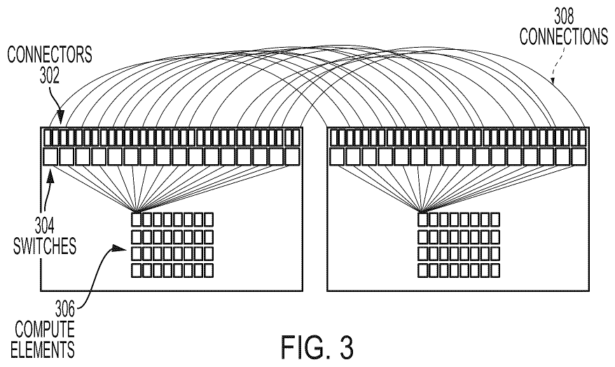

FIG. 3 illustrates connected boards according to some embodiments. The system comprises Connectors 302, Switches 304, Compute Elements 306, and Connections 308. As illustrated, an all to all connection embodiment is presented. Every one of Switches 304 on a single board is connected to each one of the Switches 304 on another board. A single one of the Connections 308 may connect two Switches 304 on two boards. Every two boards (N=2) may be connected with multiple cables, (for example 16). The Number of cables then may be calculated according to the formula:

N*(N−1)/2*16

As more and more boards are connected, too much space, noise and crosstalk may make connections less feasible. For example, using 32 boards may use up to 7,936 Connections 308. In the illustrated example, 32 Compute Elements 406 are present. In connecting the boards in a vertical manner, rather than orthogonally as in FIG. 2, the cabling may become more difficult.

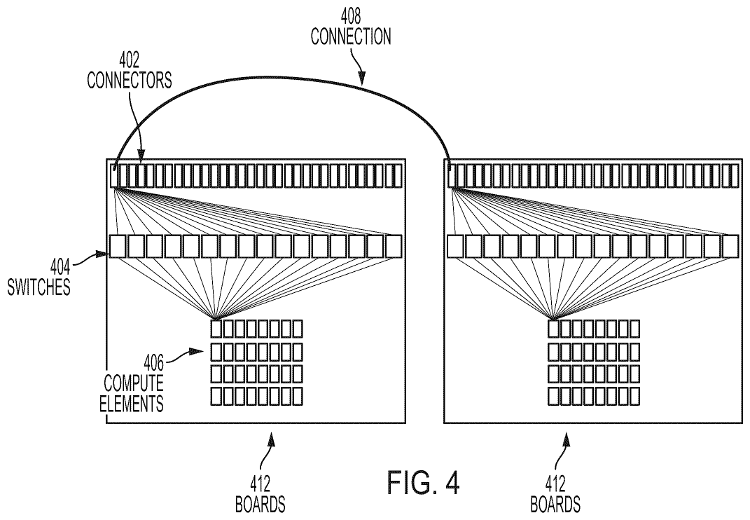

FIG. 4 illustrates connected PCBs according to various embodiments. The system comprises Connectors 402, Switches 404, Compute Elements 406, and PCBs 412. In one embodiment, there may be 32 PCBs 412 or boards in a Data Center Rack 104. Any number of PCBs 412 may be considered. For example, when one rack has 32 PCBs 412 which each have 32 Compute Elements 406, then there may be a total of 1024 compute elements connected on a single rack. Any variation on the number of PCBs 412 and Compute Elements 406 on each PCBs 412 may be considered. For example, one of the PCBs 412 may have 8, 16, 24 or 32 compute elements. This is intended as illustrative and not limiting.

In some embodiments, every one of Switches 404 may connect to every one of Connectors 402. As illustrated, all of Switches 404 are connected to a single one of Connectors 402 to illustrate the design. However, in some embodiments, the fanout illustrated from one of Switches 404 to one of Connectors 402 may occur with each and every one of Switches 404 (not illustrated). Therefore, with every one of Switches 404 connected to every one of Connectors 402, one Connection 408 may be used to connect to another one of the PCBs 412. The wires from all switches on one PCB may be used to connect up to another PCB using a single connector. A single connector on each PCB allows one cable to connect each switch (16 illustrated) to its partner switch on 2 PCBs. For example, the leftmost switch of one board may connect to the leftmost switch of another board. The 2^{nd} from left switch of one board may connect to the 2^{nd} from left switch of another board, etc. Every 2 boards, where N=2 are connected with one cable. The number of cables may be presented by:

N*(N−1)/2

A larger node using 32 PCBs may have 496 cables. This example is illustrative and not meant to be limiting.

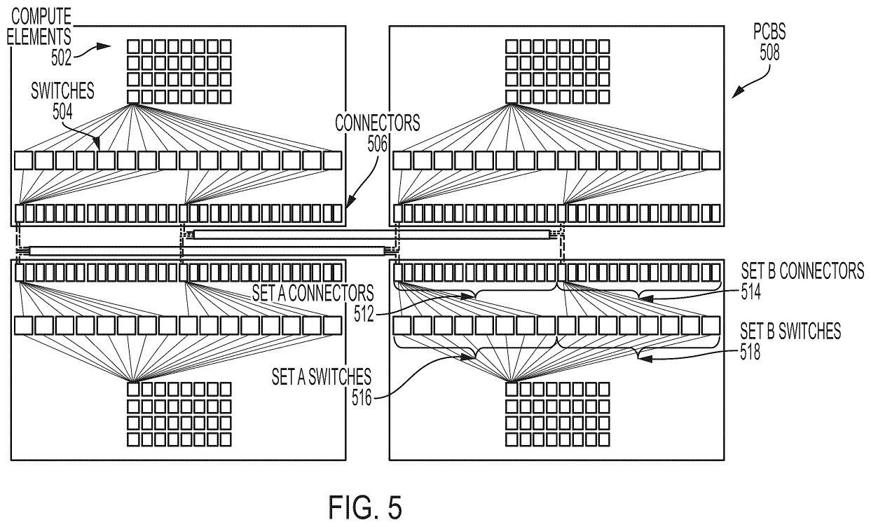

FIG. 5 illustrates connected PCBs according to some embodiments. The system comprises Compute Elements 502, Switches 504, Connectors 506, and PCBs 508. As illustrated, any variation on the number of fanout connections from Switches 504 to Connectors 506 may be used. In FIG. 5, ½ of the fanout of FIG. 4 is illustrated. For example, ½ of the Switches 504 may each connect to ½ of the Connectors 506 on each PCB.

In one example, all of Set A Switches 516 may each be connected to each of Set A Connectors 512. All of Set B Switches 518 may each be connected to each of Set B Connectors 514. In some embodiments, each of the Compute Elements 502 may be connected to each of the Switches 504 on each of the PCBs 508.

In the illustrated example, Set A Switches 516 are connected to Set A Connectors 512. Set A Connectors 512 comprises 16 connectors, and Set A Switches 516 comprises 8 switches. Therefore, 128 wired fanout connections would be made between Set A Connectors 512 and Set A Switches 516 (8 switches*16 connectors). A similar number of wires or connections used for board signal routing would be used for Set B Switches 518 connections to Set B Connectors 514. Comparably, as there are 32 Compute Elements, there would be 512 connections on each PCB (as illustrated) for each of Compute Elements 502 to connect to each of Switches 504 (32 Compute Elements*16 total connectors).

As illustrated, because Set A Connectors 512 and Set B Connectors 514 are each ½ of the overall connectors on the PCB, the connections exiting from each connector from Set A Connectors 512 and each connector from Set B Connectors 514 would connect to 2 different boards, making Set A Connectors 512 ultimately connect to all of the boards on the same rack and Set B Connectors 514 ultimately connect to all of the boards on the same rack. In other words, an individual connector connects to two boards, but the set (as illustrated ½ of the connectors) would connect to all of the boards. If the Set A Connectors 512 and Set B Connectors 514 were ¼ of the connections (not illustrated), then the connections exiting from the respective ¼ set of the connections would each connect to 4 other PCBs. Similarly, in some embodiments, when Set A Connectors 512 and Set B Connectors 514 are each ⅛ of the connectors, then each of the connectors would connect to 8 other PCBs. As illustrated, a small fanout may occur on the connections as well with this division of connections to other PCBs.

In one example embodiment, the fanout may occur on the PCB in between switches and connectors, as well as in the cable. The wires from all switches on one PCB that are used to connect up to another PCB may go to 2 connectors. Two connectors on each board may allow 2 cables to connect each switch on one PCB with its partner switch on another PCB. Every 4 PCBs (N=4) may be connected with 2 cables. A node with 32 boards and a cable fanout of 2 may need 136 cables, according to the following equation:

Number of cables=((N/Fanout)*((N/Fanout)−1))/2+N/2

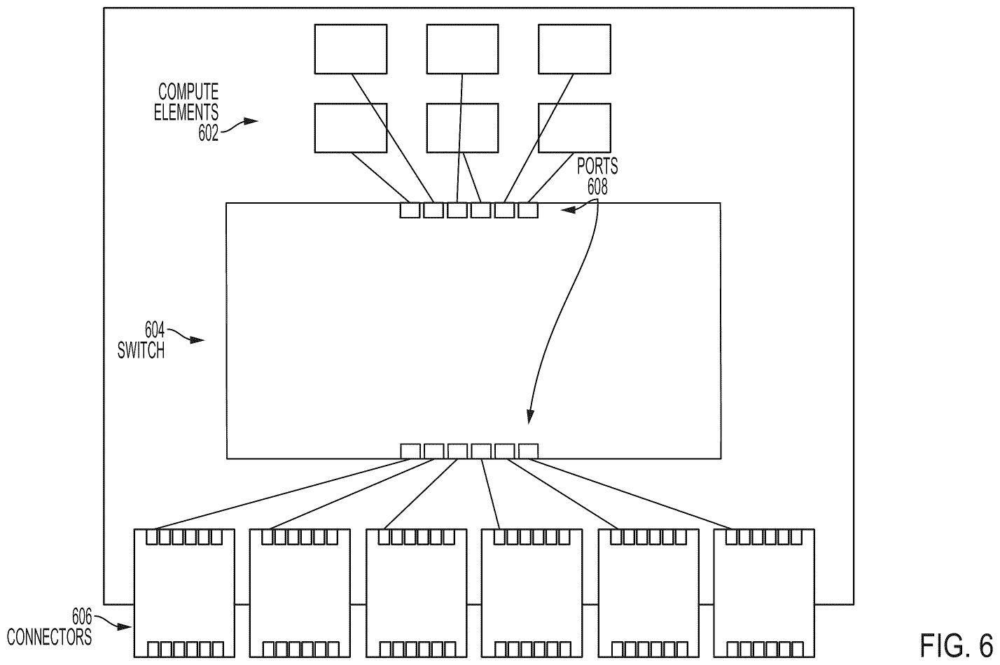

FIG. 6 illustrates an example embodiment of a detailed switch and board structure. The system comprises Compute Elements 602, a Switch 604, and Connectors 606. As illustrated, each of the compute elements are connected to a port of the switch. Each of the remaining ports of the Switch 604 connect to one of the Connectors 606. In FIG. 6, there are 6 connectors illustrated, for simplicity and to illustrate how each switch, connector and compute element may be connected. Any number of Compute Elements 602, Connectors 606 and Switches 604 may be used. For example, a single board may contain 2, 4, 8, 16, or 32 Connectors 606, Switches 604 and Compute Elements 602. These numbers are merely illustrative and not intended as limiting.

In an embodiment where less than an all to all mapping between switches and connectors is used, the mapping between Connectors 606 and Switches 604 may be mapped and connected accordingly. For example, when half of the Switches 604 are connected to half of the Connectors 606 the illustration in FIG. 6 would have connections between Switch 604 to half of Connectors 606. In a similar manner, when one quarter of the switches are connected to one quarter of the connectors each of the outgoing ports on each switch may be mapped to one quarter of the switches (not illustrated). In this manner any number or variation on the number of fanout between the Switch 604 and Connectors 606 may be considered.

Embodiments of the subject matter and the operations described in this specification may be implemented in digital electronic circuitry, in computer software, firmware, and/or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively, or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may include many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a plurality of connectors;
a plurality of switches; and
a plurality of compute elements, wherein each of the plurality of compute elements is connected to each of the plurality of switches, and a first subset of the plurality of switches is directly connected via a first mechanism to a first subset of the plurality of the connectors, and a second subset of the plurality of switches is directly connected via a second mechanism to a second subset of the plurality of the connectors.

2. The device of claim 1, wherein the device is a Printed Circuit Board (PCB) that connects to other PCBs via the plurality of connectors, as part of a High-Performance Computing (HPC) system.

3. The device of claim 1, where the first plurality of switches is half of the plurality of switches and the first subset of the plurality of connectors is half of the plurality of connectors.

4. The device of claim 3, wherein the device is a Printed Circuit Board (PCB) that connects to other PCBs via the plurality of connectors and each connector of the plurality of connectors connects to two other PCBs.

5. The device of claim 1, where the first plurality of switches and second plurality of switches is each one quarter of the plurality of switches and the first subset of the plurality of connectors and second plurality of connectors is each one quarter of the plurality of connectors.

6. The device of claim 5, where the device is a Printed Circuit Board (PCB) and each of the plurality of connectors connects to 4 other PCBs.

7. The device of claim 1, where each of the plurality of compute elements is one of:
a Graphics Processing Units (GPUs), Central Processing Units (CPUs), Tensor Processing Units (TPUs), Neural Processing Units (NPUs), Vision Processing Units (VPUs), Field Programmable Gate Arrays (FPGAs), or a Microprocessor.

8. The device of claim 1, wherein the first and second mechanisms are each fanouts.

9. A device comprising:
a plurality of connectors;
a plurality of switches; and
a plurality of compute elements, where each of the plurality of compute elements is directly connected via a mechanism to each of the plurality of switches, and the plurality of switches is each connected to the plurality of the connectors, and each of the plurality of the connectors connects to one other device.

10. The device of claim 9, wherein the device is a Printed Circuit Board (PCB) that connects to other PCBs via the plurality of connectors and each connector of the plurality of connectors connects to one other PCB.

11. The device of claim 10, wherein the PCB and the other PCB are from a plurality of PCBs in a rack in a datacenter.

12. The device of claim 11, wherein the rack has a routing device which routes tasks to a plurality of compute elements on each of the plurality of PCBs in the rack.

13. The device of claim 9, wherein the device is a Printed Circuit Board (PCB) that connects to other PCBs via the plurality of connectors, as part of a High-Performance Computing (HPC) system.

14. The device of claim 9, where each of the plurality of compute elements is one of:
a Graphics Processing Units (GPUs), Central Processing Units (CPUs), Tensor Processing Units (TPUs), Neural Processing Units (NPUs), Vision Processing Units (VPUs), Field Programmable Gate Arrays (FPGAs), or a Microprocessor.

15. The device of claim 9, wherein the mechanism is a fanout.

16. A high-performance computing system comprising:
a plurality of circuit boards each including a plurality of compute elements, a plurality of switches, and a plurality of connectors,
where each of the plurality of circuit boards is connected wherein each of the plurality of compute elements is connected to each of the plurality of switches, and a first subset of the plurality of switches is directly connected to a first subset of the plurality of the connectors via a first mechanism, and a second subset of the plurality of switches is directly connected to a second subset of the plurality of the connectors via a second mechanism on its respective circuit board of the plurality of circuit boards.

17. The high-performance computing system of claim 16, where the first plurality of switches is half of the plurality of switches and the first subset of the plurality of connectors is half of the plurality of connectors.

18. The high-performance computing system of claim 16, where each of the plurality of compute elements is one of:
a Graphics Processing Units (GPUs), Central Processing Units (CPUs), Tensor Processing Units (TPUs), Neural Processing Units (NPUs), Vision Processing Units (VPUs), Field Programmable Gate Arrays (FPGAs), or a Microprocessor.

19. The high-performance computing system of claim 16, further comprising a routing device connected to the plurality of circuit boards which routes tasks to the plurality of compute elements.

20. The high-performance computing system of claim 19, wherein the routing device communicates with the plurality of compute elements and performs throttling to manage the bandwidth and processing loads of the plurality of circuit boards and compute elements.
